(19) United States
(12) Patent Application Publication
(10) Pub. No.: US 2025/0024639 A1
(43) Pub. Date: Jan. 16, 2025

(54) BAFFLE ASSEMBLY FOR USE IN AN IMMERSION COOLING SYSTEM

(71) Applicant: LIQUIDSTACK HOLDING B.V., Amsterdam (NL)

(72) Inventors: Kar-Wing Lau, Hong Kong (HK); Wai Sing Cheng, Hong Kong (HK); Joseph Capes, Northborough, MA (US)

(21) Appl. No.: 18/772,200

(22) Filed: Jul. 14, 2024

Related U.S. Application Data
(63) Continuation of application No. PCT/IB2023/000024, filed on Jan. 15, 2023.
(60) Provisional application No. 63/299,956, filed on Jan. 15, 2022.

(51) Int. Cl. H05K 7/20

(52) U.S. Cl. CPC H05K 7/203; H05K 7/20327; H05K 7/20818

(57) ABSTRACT

A two-phase immersion cooling system may include an immersion tank containing dielectric fluid. When cooling an electronic device that is immersed in the dielectric fluid, vigorous boiling may occur proximate to the device, and a stream of vapor bubbles may be produced. To prevent the stream of vapor bubbles from adversely affecting cooling performance elsewhere in the immersion tank, a baffle assembly may be provided. The baffle assembly may be removably attachable to the electronic device. In one embodiment, the baffle assembly may include a plate having one or more slots. The baffle assembly may include one or more posts extending from the plate and being configured to attach to a substrate of the electronic device. The baffle assembly may include a baffle that is removably attachable to the one or more slots. Other examples may be claimed or described.

### CROSS-REFERENCE TO RELATED APPLICATIONS

Pursuant to 35 U.S.C. 120 and 365(c), this application is a continuation of International Application PCT/IB2023/000024, filed on Jan. 15, 2023, which designates the United States and claims priority to U.S. Patent Application No. 63/299,956, filed on Jan. 15, 2022, which is hereby incorporated by reference in its entirety.

### TECHNICAL FIELD

The present disclosure relates to immersion cooling systems and, more specifically, to baffle assemblies for use with electronic components in an immersion cooling tank.

### BACKGROUND

Data centers house information technology (IT) equipment for the purposes of storing, processing, and disseminating data and applications. IT equipment may include electronic devices, such as servers, storage systems, power distribution units, routers, switches, and firewalls.

IT equipment consumes electricity and produces waste heat as a byproduct. A data center with many servers may require a dedicated IT cooling system to manage the waste heat. If the waste heat is not removed from the data center, ambient temperature within the data center may rise above an acceptable threshold and temperature-induced performance throttling of electronic devices (e.g., microprocessors) may occur, which is undesirable.

Direct liquid cooling systems can be used to capture waste heat from IT equipment. One form of direct liquid cooling is immersion cooling. In an immersion cooling system, an electronic device is immersed in dielectric fluid. Waste heat from the electronic device is transferred to the dielectric fluid and then rejected outside the data center through a suitable heat rejection system.

Examples of immersion cooling systems include single-phase immersion cooling systems and two-phase immersion cooling systems. Single-phase immersion cooling systems rely on sensible heat transfer to remove heat from the IT equipment. Two-phase immersion cooling systems leverage both sensible and latent heat transfer to remove heat from the IT equipment. Consequently, two-phase immersion cooling systems may achieve greater local heat removal capacities and be better suited to cool IT equipment producing high heat fluxes, such as high-performance computing equipment.

### SUMMARY

In one embodiment, a baffle assembly for use in an immersion cooling system may include a plate having one or more slots. The baffle assembly may include one or more posts extending from the plate and configured to attach to a substrate of an electronic device. The one or more posts may serve to space apart the plate from the substrate by a distance when the one or more posts are attached to the substrate, thereby providing a gap between the plate and substrate. The baffle assembly may include a baffle removably attached to the one or more slots. The baffle may be repositioned and moved from a first position on the plate to a second position on the plate. A width of the baffle may be less than a width of the gap. The baffle may be angled, planar, curved, or any other shape suitable to divert vapor bubbles. The baffle may include one or more protrusions to divert vapor bubbles. The baffle may include an internal fluid passageway having an inlet and an outlet. The baffle assembly may include a one-way valve proximate to the inlet and outlet. The internal fluid passageway may be configured to receive a flow of coolant from a condenser of an immersion cooling system.

In another embodiment, a baffle assembly for use in an immersion cooling system may include a support member having a plurality of attachment features. The baffle assembly may include a plurality of spacers removably attachable to the support member and configured to attach to a substrate of an electronic device. A plurality of spacers may serve to space apart the support member from the substrate by a distance when the spacers are attached to the substrate, thereby providing a gap between the support member and substrate. The baffle assembly may include a baffle removably attachable to one or more of the attachment features. The baffle may be moved from a first position on the support member to a second position on the support member. The plurality of spacers may have adjustable lengths to allow the gap size to be adjusted. The baffle may include an internal fluid passageway having an inlet and an outlet. The baffle assembly may include a fluid supply line fluidly connected to the inlet and a fluid return line fluidly connected to the outlet. The fluid supply line and the fluid return line may removably and fluidly couple to a condenser of an immersion cooling system, thereby providing a flow of coolant through the baffle to cool the baffle and promote condensing of vapor bubbles near the baffle.

In another embodiment, a method of adjusting a baffle assembly for an immersion cooling system may include providing a baffle assembly. The baffle assembly may include a support member having a first plurality of attachment features. The baffle assembly may include a plurality of spacers attached to the support member and configured to attach to a substrate of an electronic device. The plurality of spacers may serve to space apart the support member from the substrate by a distance when the spacers are attached to the substrate. The baffle assembly may include a baffle removably attached to one or more of the first plurality of attachment features by a second plurality of attachment features. The baffle may be located at a first position on the support member. The method may include removing the baffle from the first position (e.g., by pulling on the baffle). The method may include reattaching the baffle to the support member at a second location by inserting the one or more attachment features of the baffle into one or more corresponding attachment features of the support member. The first plurality of attachment features may include a plurality of slots. The second plurality of attachment features may include a plurality of tabs. The plurality of spacers may include a plurality of posts. The baffle may include an internal fluid passageway having an inlet and an outlet. The baffle assembly may include a one-way valve proximate to the inlet. The baffle assembly may include a fluid supply line fluidly connected to the inlet and a fluid return line fluidly connected to the outlet. The fluid supply line and the fluid return line may removably and fluidly couple to a condenser of an immersion cooling system, thereby providing a flow of coolant through the baffle to cool the baffle and promote condensing of vapor bubbles near the baffle.

### BRIEF DESCRIPTION OF DRAWINGS

In the drawings, like reference characters generally refer to the same parts throughout the different views. Also, the drawings are not necessarily to scale, emphasis instead being placed upon illustrating principles of the invention. In the following description, various embodiments are described with reference to the following drawings, in which:

FIG. 1 shows a perspective view of an immersion cooling system having an immersion tank.

FIG. 2 shows a semi-transparent view of the immersion cooling system of FIG. 1 with a lid removed, revealing a condenser and a plurality of computer servers located in the immersion tank.

FIG. 3 shows a semi-transparent view of the immersion cooling system of FIG. 1 with a plurality of baffle assemblies in the immersion tank.

FIG. 4 shows a semi-transparent view of the immersion cooling system of FIG. 1 with dielectric fluid in the immersion tank.

FIG. 5 shows a perspective view of a baffle assembly attached to a substrate of an electronic device.

FIG. 6 shows a side perspective view of FIG. 5.

FIG. 7 shows an exploded view of the baffle assembly and electronic device of FIG. 5.

FIG. 8A shows a perspective view of a stack of baffle assemblies, each attached to a substrate of an electronic device.

FIG. 8B shows an enlarged view of FIG. 8A with an example V-shaped baffle.

FIG. 8C shows an enlarged view of FIG. 8A with an example planar-shaped baffle.

FIG. 9 shows an exploded view of a prior art microprocessor assembly having an integrated heat spreader.

FIG. 10 shows a bottom perspective view of the integrated heat spreader of FIG. 9 with thermal paste, which is prior art.

FIG. 11 shows a baffle assembly attached to a substrate of a microprocessor.

FIG. 12 shows a semi-transparent view of FIG. 11 to reveal the baffle and mounting post of the baffle assembly.

FIG. 13A shows a baffle assembly with a pair of baffles attached to a plate in a first position.

FIG. 13B shows a step of detaching the pair of baffles of FIG. 13A from the plate.

FIG. 13C shows a step of moving the pair of baffles of FIG. 13A to a second position.

FIG. 13D shows a step of attaching the pair of baffles of FIG. 13A to the plate at the second position.

FIG. 14 shows an embodiment of a baffle assembly with an angled baffle and a baffle with protrusions.

FIG. 15 shows an embodiment of a baffle assembly with an angled baffle and a curved baffle.

FIG. 16 shows an angled baffle with tabs.

FIG. 17 shows a cross-sectional side view of baffle with an inner fluid passageway fluidly connected to a condenser of an immersion cooling system.

FIG. 18 shows a planar baffle with an inner fluid passageway.

### DETAILED DESCRIPTION OF EMBODIMENTS

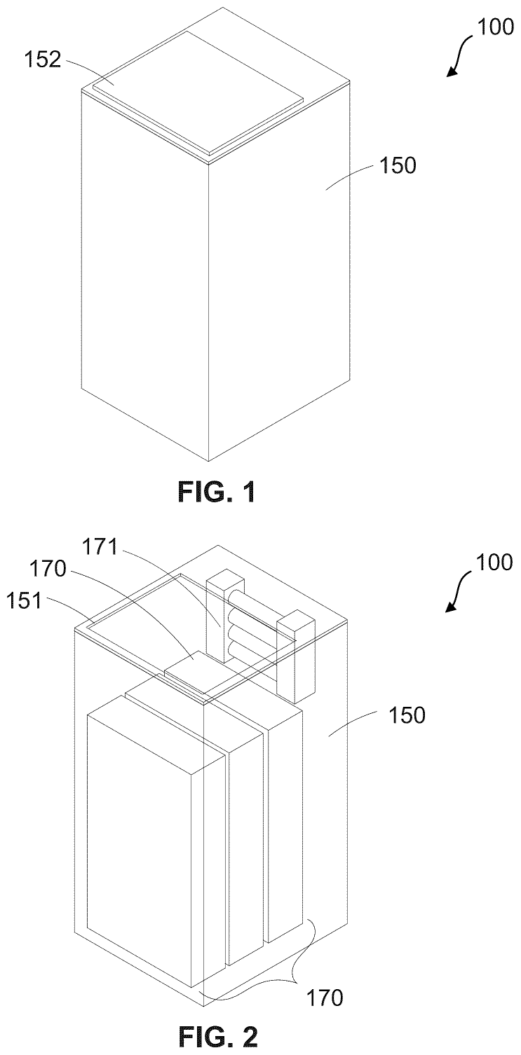

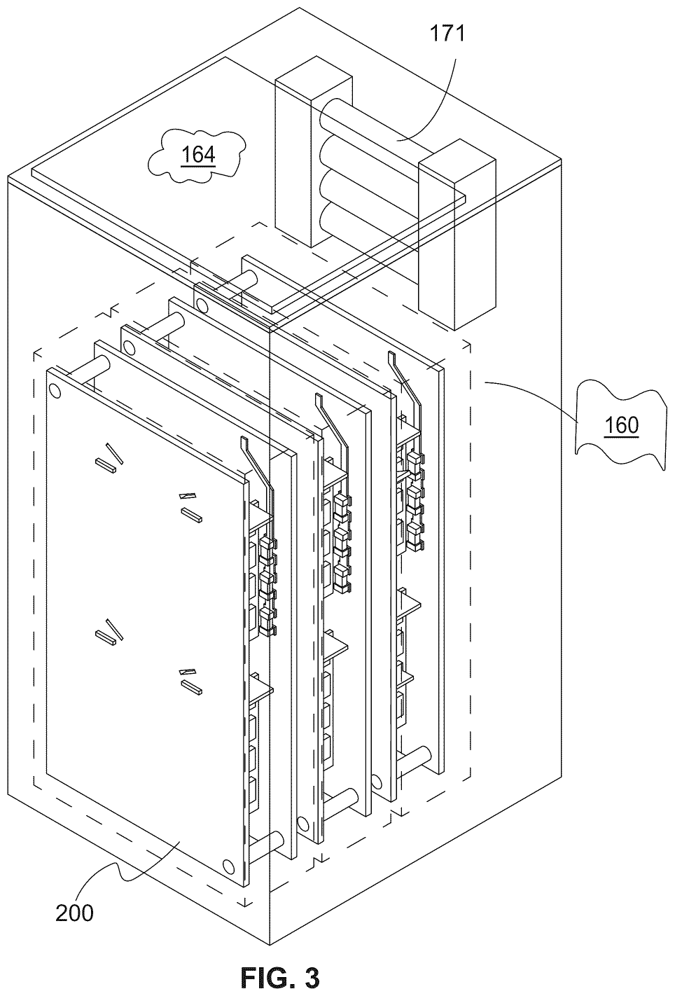

FIG. 1 shows an immersion cooling system 100. The immersion cooling system may include an immersion tank 150. The immersion tank may include an opening 151 covered by a lid 152. The opening 151 may be located at or near a top portion of the immersion tank 150 and provide access to an interior volume of the immersion tank.

As shown in FIG. 2, the immersion tank 150 may be configured to receive one or more electronic devices 170, such as one or more computer servers 170 or network communication devices in an interior volume of the immersion tank 150. In the embodiment shown in FIG. 2, the electronic devices 170 may be arranged in substantially upright orientations and adjacent to each other to form a stack, to utilize available space.

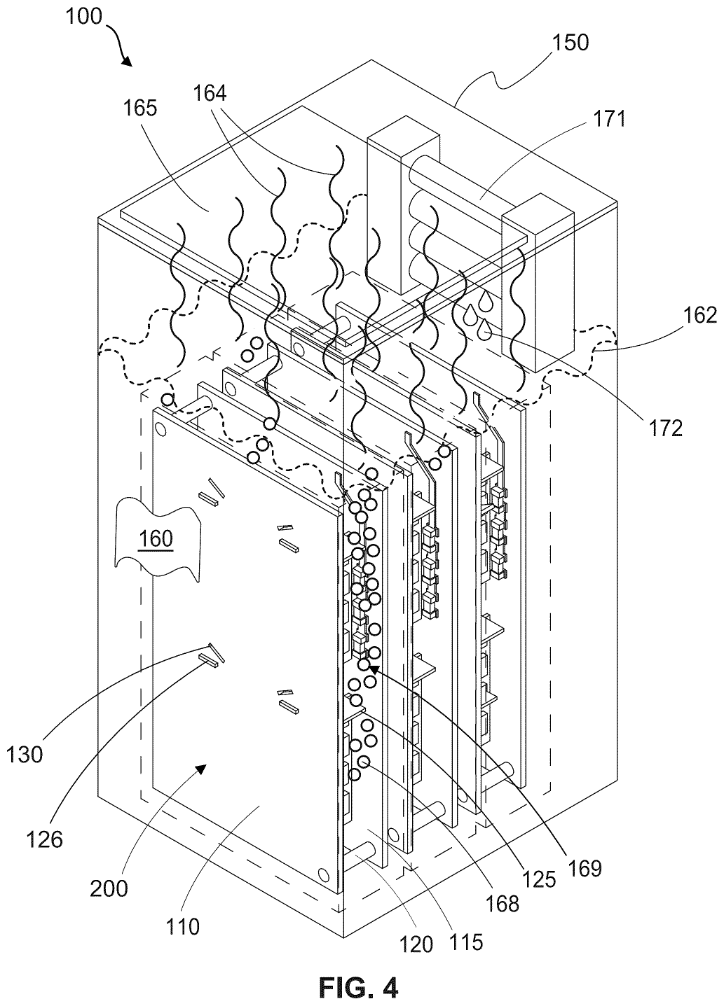

As shown in FIG. 4, the immersion cooling system may be configured to operate as a two-phase immersion cooling system 100. The immersion tank 150 may be partially filled with dielectric fluid 160 in liquid phase. The electronic devices 170 may be fully immersed in the dielectric fluid 160. The electronic devices 170 may include microprocessors 140 and other heat-dissipating components 145 (e.g., memory, power supply, etc.).

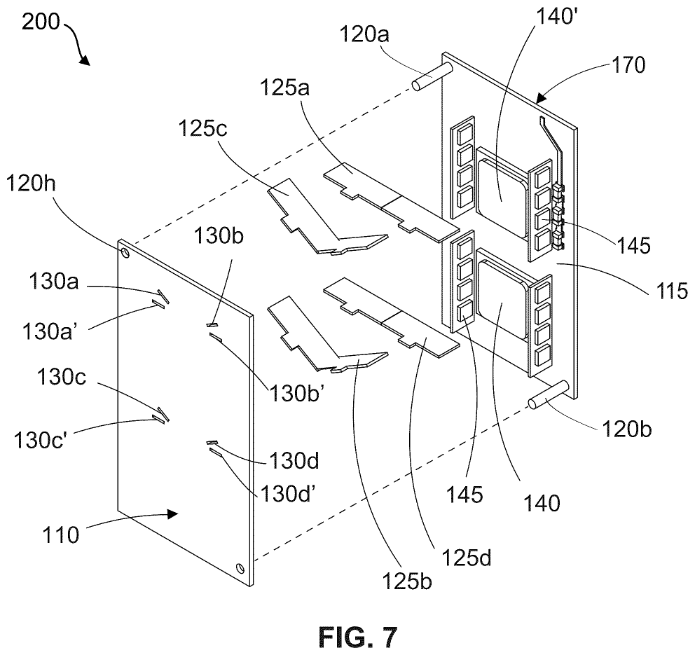

During operation, localized boiling may occur as heat from the electronic device vaporizes dielectric fluid 160 adjacent to the device. The localized boiling may produce vapor bubbles 168 that, due to buoyancy, flow upward through the dielectric liquid 162 column. When the electronic device 170 is producing a high heat flux, such as in the case of a fully utilized central processing unit (CPU) or graphics processing unit (GPU), vigorous boiling may occur proximate to the device, and a stream of vapor bubbles 169 may be produced and rise through the fluid column, as shown in FIG. 4. As the bubbles rise, they may expand and grow due to a reduction in hydrostatic pressure. The stream of vapor bubbles 169 may displace dielectric liquid and adversely impact cooling performance near the stream of vapor bubbles. This occurs, for example, when the electronic device 170 has two microprocessors and one microprocessor is mounted directly above the other microprocessor on a circuit board (see example orientation in FIG. 7). As a stream of vapor bubbles rises from the first microprocessor, the vapor bubbles may displace dielectric liquid at or near the second microprocessor, thereby inhibiting the flow of subcooled liquid 160 to a surface of the second microprocessor. The inhibited flow of subcooled liquid may result in the second processor being insufficiently cooled and, in extreme cases, may result in dryout at a surface of the second microprocessor and potential throttling or failure. Therefore, it is desirable to control streams of vapor bubbles 169 within the immersion tank 150. More specifically, it is desirable to divert streams of vapor bubbles 169 away from electronic devices 170 that produce high heat fluxes to avoid problems caused by inadequate cooling, such as throttling or failure.

Various embodiments of baffle assemblies are described herein. The baffle assemblies may be configured to divert vapor bubbles within an immersion tank 150. In some examples, the baffle assemblies may be reconfigurable to allow the assemblies to be used with more than one electronic device 170. For example, when a new server replaces an older server in the immersion tank 150 (e.g., due to servicing or replacement), the reconfigurable baffle assemblies may be transferred from the older server to the new server, and the baffles may be repositioned to accommodate a different circuit board layout of the new server.

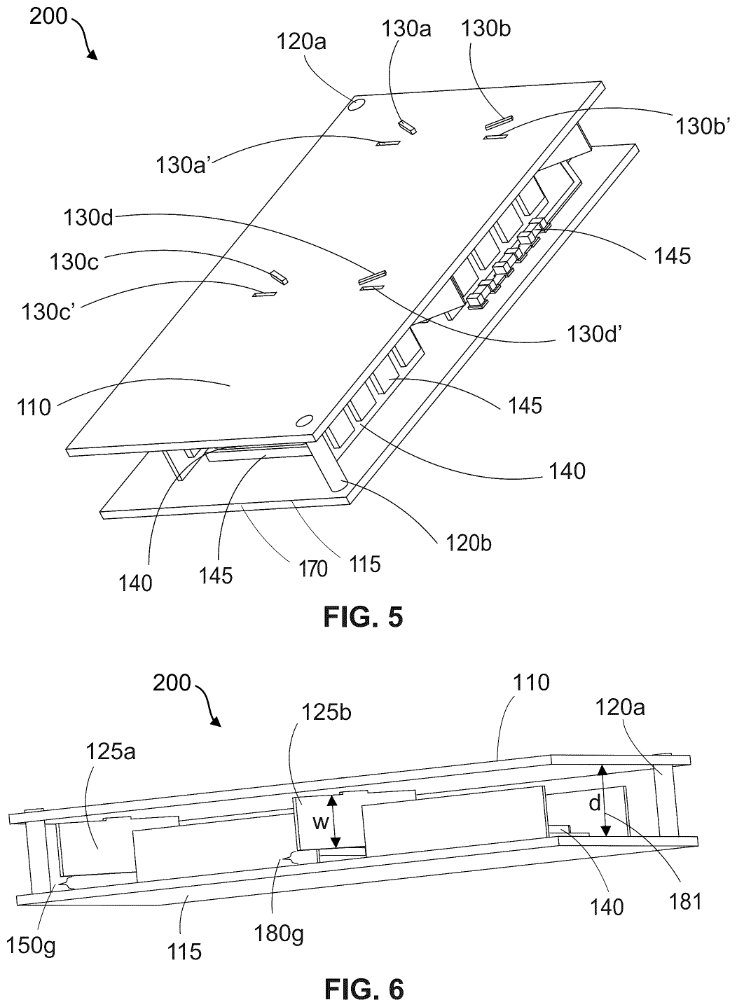

In an embodiment shown in FIG. 5, a baffle assembly 200 may include a support member 110. The support member 110 may be, for example, a plate, substrate, or any other suitable support structure capable of receiving one or more baffles and attaching to an electronic device 170. The baffle assembly 200 may include one or more spacers 120 extending outward from a surface of the support member 110. The spacers 120 may be any suitable spacers, such as posts as shown in FIG. 5. The spacers 120 may be configured to attach (e.g., with fasteners) to a substrate 115 of an electronic device 170. The spacers 120 may serve to space apart the support member 110 from the substrate 115 by a distance (d), as shown in FIG. 6. The distance (d) may provide a suitable gap that allow vapor bubbles to travel upward without undue flow restriction. In some examples, the spacers 120 may have adjustable lengths to enable adjustment of the gap size. Together, the support member 110 and the substrate 120 may define opposing walls of a vertical channel that prevents rising vapor bubbles in the channel from reaching and adversely impacting cooling of an adjacent server, as shown in FIG. 4. The spacers 120 may be adjustable in length to allow the baffle assembly 200 to be configured for a specific application. Alternatively, the baffle assembly 200 may be a kit that includes an assortment of spacers of various lengths that can be selectively installed to adjust the distance (d) for a specific application.

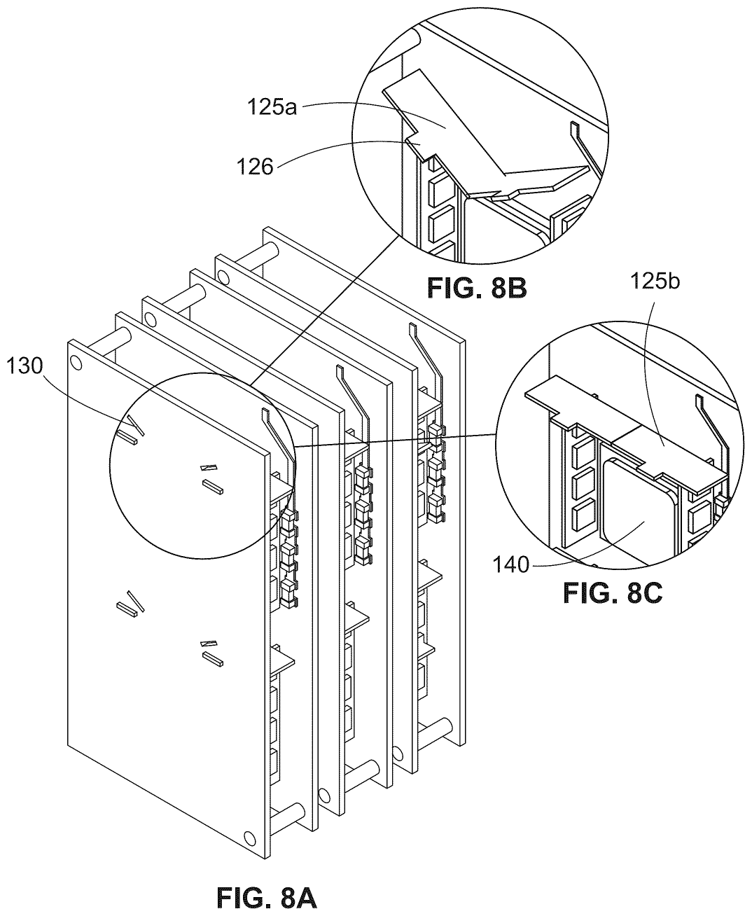

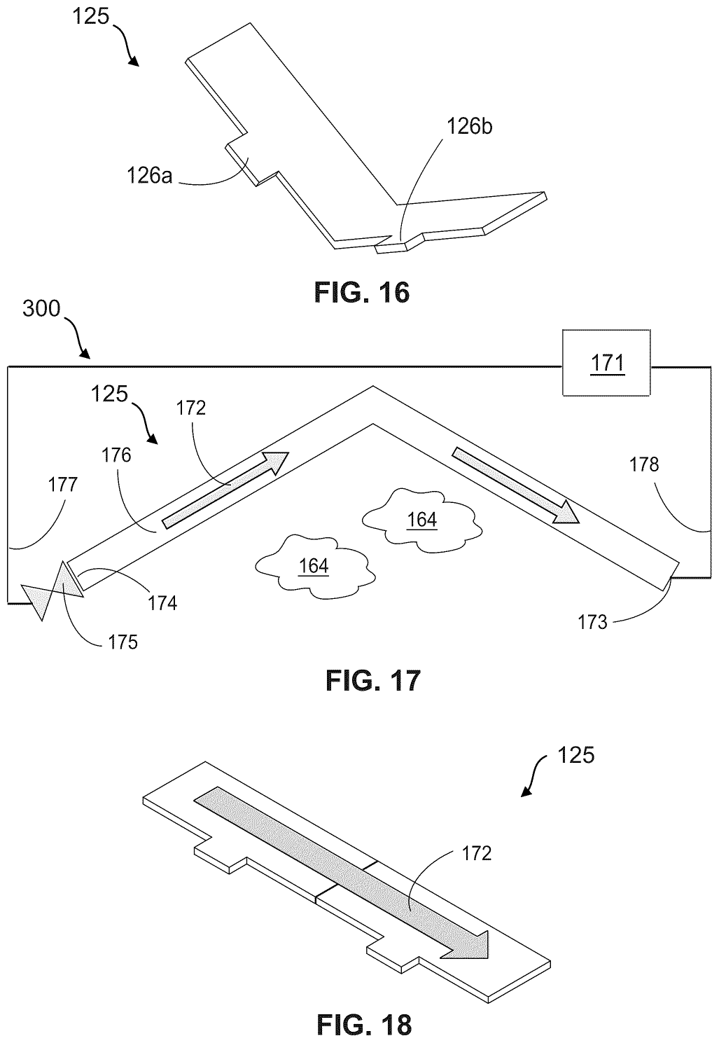

The baffle assembly 200 may include a baffle 125, as shown in FIG. 16. The baffle 125 may be removably attachable to the support member 110 by one or more attachment features. For example, the baffle 125 may include one or more tabs that are insertable into corresponding slots in the support member 110 to facilitate removable attachment. In the example shown in FIG. 16, the baffle 125 may include a first tab 126a and a second tab 126b. Each tab 126 may be insertable into a corresponding slot 130 in the support member 110, as shown in FIG. 8A-8C. In FIGS. 8A and 8C, alternative options of an angled baffle and a planar baffle are shown, respectively. The angled baffle may be suitable for dividing and diverting a stream of vapor bubbles 169 into two separate streams of vapor bubbles, thereby reducing the likelihood of the stream of vapor bubbles causing cooling issues elsewhere in the fluid bath.

As shown in FIG. 6, the baffle 125 may be attached to the support member 110 and have a width (w) that extends across a portion of a gap 181, defined by the distance (d), between the substrate 115 and the support member 120. The gap 181 may have a suitable size to allow vapor bubbles to flow without undue restriction.

In some baffle assemblies 200, the support surface 110 may be reversable or rotatable. For example, the baffle support surface 110 may attach to the substrate by two spacers (120a, 120b) located at opposing corners of the support surface 110. Consequently, the support surface 110 can be rotated 180 degrees and reattached to the spacers (120a, 120b), resulting in repositioning of the slots (130a, 130a′, 130b, 130b′, 130c, 130c′, 130d, 130d′), which may be useful when adapting the baffle assembly 200 for a specific application.

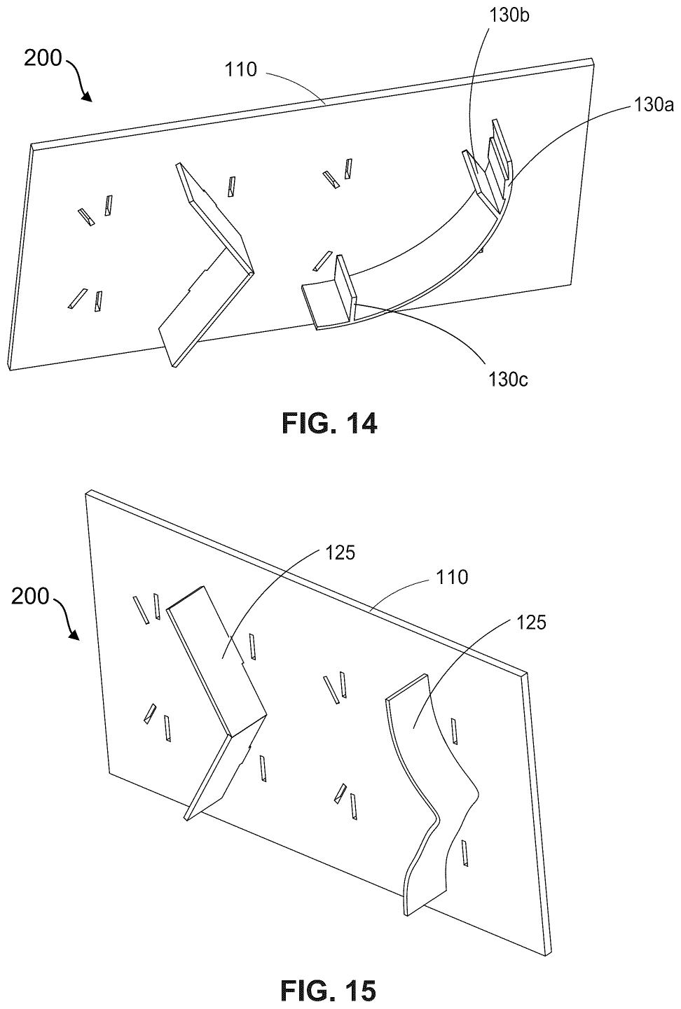

The baffle 125 may be selected from a variety of shapes to suit specific applications. For example, the baffle may be planar, as shown in FIGS. 7 and 8C. The baffle may be angled, as shown in FIGS. 7, 8B, and 16. The baffle may have protrusions (130a, 130b), as shown in FIG. 14. The baffle may have curved portions, as shown in FIG. 15. The baffles may be any other suitable shape or combination of shapes. In another example, the baffles may be bendable to allow additional customization. In each application, the baffle 125 may be configured to divert or guide the stream of vapor bubbles 169 within the immersion tank and thereby prevent the vapor bubbles from adversely affecting cooling performance elsewhere in the tank.

The baffle assembly 200 may include more than one baffle, as shown in the exploded view of FIG. 7. The support member 110 may include a plurality of slots to accommodate multiple baffles. A first grouping of slots (130a, 130b, 130a′, 130b′) may be configured to receive an angled baffle 125c or a planar baffle 125a. A second grouping of slots (130c, 130d, 130c′, 130d′) may be configured to receive an angled baffle 125b or a planar baffle 125d. Depending on an application, a user may select two angled baffles, two planar baffles, a combination of one angled baffle and one planar baffle, a single baffle, or no baffle. For the electronic device 170 shown in FIG. 7, positioning a baffle at the second grouping of slots (130c, 130d, 130c′, 130d′) may be desirable to prevent a stream of vapor bubbles that are rising from the first microprocessor from flowing past the second microprocessor and inhibiting the flow of subcooled dielectric fluid to cool the second microprocessor 140′.

As shown in FIG. 6, each baffle (125a, 125b) may not extend the full distance (d) between the substrate 115 and the support member 110. A gap 150g may exist between the baffle and the substrate. The gap 150 may prevent the baffle from contacting or otherwise abrading the substrate 110 (e.g., when the baffle is being impacted by a continuous stream of vapor bubbles for an extended period). The gap 150 may prevent the baffles from overly restricting vapor flow and provides a pathway for vapor bubbles to escape upward as they rise in the fluid column.

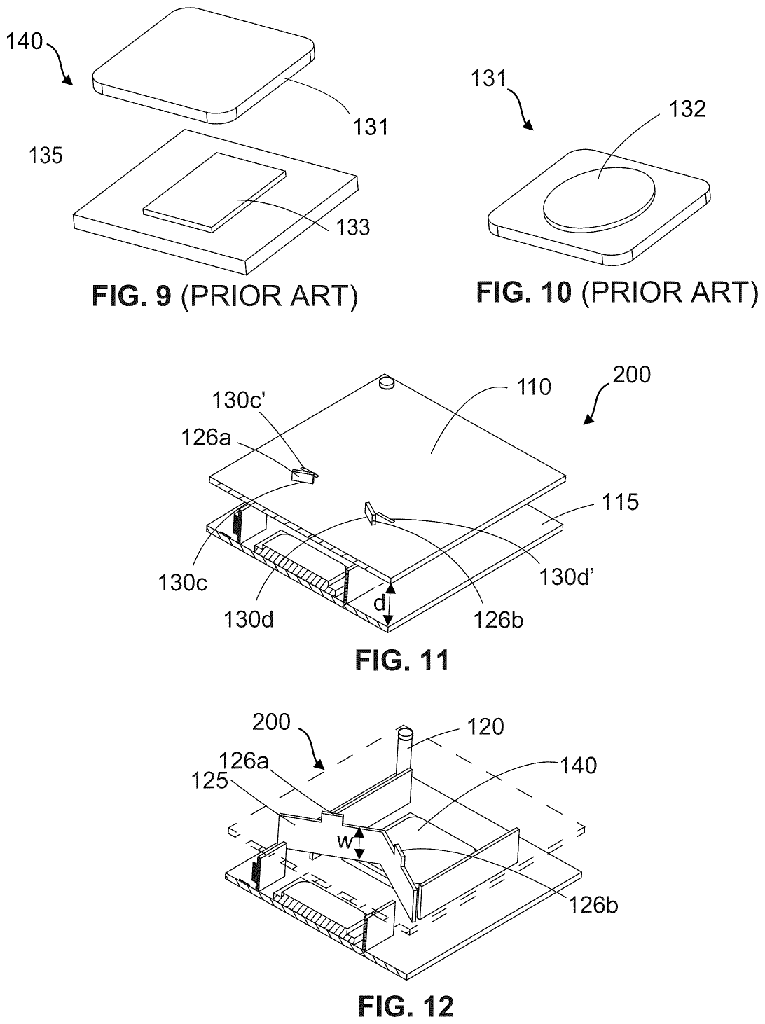

FIG. 9 shows an exploded view of a prior art microprocessor 140. The microprocessor 140 may include a chip 133 on a substrate 135. An integrated heat spreader 131 may cover and protect the chip 133. A layer of thermal paste 132 may be applied between a top surface of the chip 133 and a bottom surface of the integrated heat spreader 131. Heat produced by the chip 133 during operation may conduct through the thermal paste 132 (see FIG. 10) to the integrated heat spreader 131. The baffle assemblies 200 described herein may be suitable for use with microprocessors 140 with or without integrated heat spreaders 131.

FIGS. 11 and 12 show a baffle assembly for a microprocessor 140, such as the microprocessor shown in FIGS. 9 and 10. The baffle assembly 300 may include a support member 110, a spacer 120, and a baffle 125. The spacer 120 may be attached to the substrate 115 of the microprocessor 140. The support member 110 may be attached to the spacer 120 and, consequently, spaced apart from the substrate 115 by a suitable distance to allow vapor bubbles to travel upward through the gap without undue restriction. The baffle 125 may be attached to the support member 110 and have a width (w) that extends across a portion of a gap between the substrate 115 and the support member 120 that is defined by the distance (d). Due to its relatively small size, the baffle assembly 200 of FIGS. 11 and 12 may have only one spacer 120.

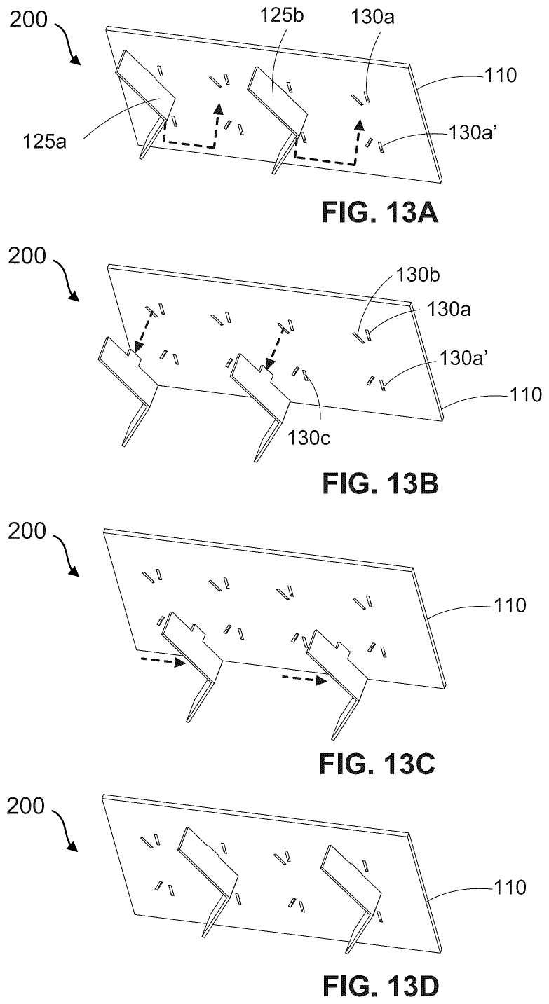

FIGS. 13A-D show a method of repositioning a pair of baffles of the baffle assembly 200. FIG. 13A shows the baffle assembly 200 with a pair of baffles (125a, 125b) that are attached to the support member 110 in a first position. FIG. 13B shows a step of detaching the pair of baffles from the support member 110 by pulling on the baffles to release tabs of the baffles from slots of the support member. FIG. 13C shows a step of moving the pair of baffles to a second position. FIG. 13D shows a step of attaching the pair of baffles to the support member at the second position by inserting tabs of the baffles into slots of the support member.

In some examples, the baffle 125 may include an internal fluid passageway. FIG. 17 shows an example of an angled baffle 125 with an internal fluid passageway 176. The internal fluid passageway 176 may have an inlet 174 and an outlet 173. The baffle assembly 200 may include a fluid supply line fluidly connected to the condenser 171 and a fluid return line fluidly connected to the condenser 171 to provide a cooling loop 300. During use, coolant (e.g., a water-glycol mixture) from the condenser 170 may flow through the internal fluid passageway 176. The baffle assembly 200 may include a one-way valve to provide one-directional flow through the internal fluid passageway. In the example shown in FIG. 17, the one-way valve 175 may be attached at or proximate to the inlet 174 of the baffle 125. The flow of coolant through the internal fluid passageway 176 may serve to cool exterior surfaces of the baffle and promote condensing of vapor (e.g., vapor bubbles) proximate to the baffle. By condensing vapor within the fluid column, a quantity and volume of vapor bubbles in the stream of vapor bubbles 169 may be reduced, thereby decreasing the likelihood of those vapor bubbles adversely impacting cooling performance elsewhere in the fluid bath.

In another embodiment shown in FIG. 18, the baffle 125 may be a planar baffle with an internal fluid passageway configured to allow a flow of subcooled liquid in one direction 172.

When the vapor bubbles pass through a liquid line 162, they may collect as dielectric vapor 164 in a headspace 165 of the immersion tank 150. The system 100 may include a condenser 171 in the headspace of the immersion tank 150, above the liquid line 162. The condenser may be configured to remove heat from the dielectric vapor 164 and cause the vapor to change back to liquid phase (e.g., liquid droplets 172) and return to the fluid bath by way of gravity.

The invention may be embodied in other specific forms without departing from the spirit or essential characteristics thereof. The foregoing embodiments, therefore, are to be considered in all respects illustrative rather than limiting the invention described herein. Scope of the invention is thus indicated by the appended claims, rather than by the foregoing description, and all changes that come within the meaning and range of equivalency of the claims are intended to be embraced therein.

What is claimed is:

1. A baffle assembly for use in an immersion cooling system, the baffle assembly comprising:
a plate comprising one or more slots;
one or more posts extending from the plate and configured to attach to a substrate of an electronic device, the one or more posts serving to space apart the plate from the substrate by a distance when the one or more posts are attached to the substrate; and
a baffle removably attached to the one or more slots.

2. The baffle assembly of claim 1, wherein the baffle can be moved from a first position on the plate to a second position on the plate.

3. The baffle assembly of claim 1, wherein a width of the baffle is less than the distance.

4. The baffle assembly of claim 1, wherein a shape of the baffle is selected from a group consisting of angled, planar, and curved.

5. The baffle assembly of claim 1, wherein the baffle comprises one or more protrusions.

6. The baffle assembly of claim 1, wherein the baffle comprises an internal fluid passageway having an inlet and an outlet.

7. The baffle assembly of claim 6, further comprising a one-way valve proximate to the inlet.

8. A baffle assembly for use in an immersion cooling system, the baffle assembly comprising:
a support member comprising a plurality of attachment features;
a plurality of spacers removably attachable to the support member and configured to attach to a substrate of an electronic device, the plurality of spacers serving to space apart the support member from the substrate by a distance when the spacers are attached to the substrate; and
a baffle removably attachable to one or more of the plurality of attachment features.

9. The baffle assembly of claim 8, wherein the baffle can be moved from a first position on the support member to a second position on the support member.

10. The baffle assembly of claim 8, wherein a width of the baffle is less than the distance.

11. The baffle assembly of claim 8, wherein a shape of the baffle is selected from a group consisting of angled, planar, and curved.

12. The baffle assembly of claim 8, wherein the plurality of spacers have adjustable lengths.

13. The baffle assembly of claim 8, wherein the baffle comprises an internal fluid passageway having an inlet and an outlet.

14. The baffle assembly of claim 13, wherein the baffle assembly further comprises a fluid supply line fluidly connected to the inlet and a fluid return line fluidly connected to the outlet, the fluid supply line and the fluid return line each configured to removably and fluidly couple to a condenser of an immersion cooling system.

15. A method of adjusting a baffle assembly for an immersion cooling system, the method comprising:
providing a baffle assembly comprising:
a support member comprising a first plurality of attachment features;
a plurality of spacers attached to the support member and configured to attach to a substrate of an electronic device, the plurality of spacers serving to space apart the support member from the substrate by a distance when the spacers are attached to the substrate; and
a baffle removably attached to one or more of the first plurality of attachment features by a second plurality of attachment features, the baffle being located at a first position on the support member;
removing the baffle from the first position; and
reattaching the baffle to the support member at a second location on the support member by inserting the one or more attachment features of the baffle into one or more corresponding attachment features of the support member.

16. The method of claim 15, wherein the first plurality of attachment features comprises a plurality of slots.

17. The method of claim 15, wherein the second plurality of attachment features comprises a plurality of tabs.

18. The method of claim 15, wherein the plurality of spacers comprises a plurality of posts.

19. The method of claim 15, wherein the baffle comprises an internal fluid passageway having an inlet and an outlet.

20. The method of claim 19, further comprising a one-way valve proximate to the inlet.
